(19) United States
(12) Patent Application Publication
(10) Pub. No.: US 2025/0135583 A1
(43) Pub. Date: May 1, 2025

(54) LASER SEALING METHODS WITH VARYING LASER PROFILES FOR CLOSING VENTHOLES OF MICROMECHANICAL DEVICES

(71) Applicant: Robert Bosch GmbH, Stuttgart (DE)

(72) Inventors: Bo CHENG, Malden, MA (US); Holger RUMPF, Reutlingen (DE); Jens FREY, Filderstadt (DE); Stephanie KARG, Stuttgart (DE); Tobias Joachim MENOLD, Weil der Stadt (DE); David BORBELY, Budapest (HU)

(21) Appl. No.: 18/384,848

(22) Filed: Oct. 28, 2023

(51) Int. Cl. B23K 26/354; B23K 26/0622

(52) U.S. Cl. CPC B23K 26/354; B23K 26/0622

(57) ABSTRACT

Methods of sealing a venthole of a micromechanical device. The venthole leads to a chamber that contains a device. A first laser pulse is applied to the venthole of a substrate of the micromechanical device for a first time period. The first laser pulse has a first laser intensity spatial distribution. Thereafter, a second laser pulse is applied to the venthole for a second time period. The second laser pulse has a second laser intensity spatial distribution that is different than the first laser intensity spatial distribution. The second laser pulse can be applied for a time that is different than that of the first laser pulse.

### TECHNICAL FIELD

The present disclosure relates to laser sealing methods for closing ventholes of micromechanical devices. In some particular embodiments, the laser applies multiple separate laser profiles at different times.

### BACKGROUND

Various micromechanical devices (e.g., microelectromechanical systems (MEMS), inertial measurement units (IMUs) etc.) include a venthole opening leading to a chamber that contains an encapsulated device. In recent years, a pulse laser irradiation technique has been utilized for sealing the venthole opening. This technique involves sealing the venthole opening to encapsulate gasses and critical pressure inside the device chamber of the micromechanical device.

### SUMMARY

According to an embodiment, a method of sealing a venthole of a micromechanical device includes applying a first laser pulse to a venthole of a substrate of a micromechanical device for a first time period, wherein the first laser pulse has a first laser intensity spatial distribution, and wherein the venthole leads to a chamber configured to contain a device; and then applying a second laser pulse to the venthole for a second time period, wherein the second laser pulse has a second laser intensity spatial distribution that is different than the first laser intensity spatial distribution.

According to an embodiment, a method of sealing a venthole of a micromechanical device includes providing a micromechanical device having a substrate, the substrate having an upper surface, and the substrate defining a venthole leading to a chamber configured to contain a device; applying a first laser pulse to the substrate at the venthole for a first time period, wherein the first laser pulse has a first laser intensity spatial distribution with a first laser pulse intensity at a center of the first laser pulse; and applying a second laser pulse to substrate at the venthole for a second time period, wherein the second laser pulse has a second laser intensity spatial distribution that is different than the first laser intensity spatial distribution, and wherein the second laser intensity spatial distribution has a second laser pulse intensity at a center of the second laser pulse that is less than the first laser pulse intensity at the center of the first laser pulse.

According to an embodiment, a method of controlling surface asperity during laser sealing of a venthole includes applying a first laser pulse to a venthole of a substrate, wherein the first laser pulse has a first laser intensity spatial distribution; and applying a second laser pulse to the venthole, wherein the second laser pulse has a second laser intensity spatial distribution that differs from the first laser intensity spatial distribution.

### BRIEF DESCRIPTION OF THE DRAWINGS

FIG. 1 depicts a cross-sectional view of a pulse laser irradiation technique for sealing a venthole opening of a micromechanical device.

FIG. 2 depicts a cross-sectional view of a sealed venthole after the pulse laser irradiation technique of FIG. 1.

FIG. 3A illustrates a laser pulse having a laser intensity spatial distribution in a Gaussian or “bell curve” shape, according to an embodiment. FIG. 3B illustrates the time application of the laser pulse of FIG. 3A, according to an embodiment.

FIG. 4 illustrates a pulse laser irradiation technique in which two different laser pulses are applied, wherein FIG. 4A illustrates the laser intensity spatial distribution of the first pulse being a Gaussian shape according to an embodiment, and FIG. 4B illustrates the laser intensity spatial distribution of the second pulse being a donut shape according to an embodiment. FIG. 4C illustrates the time application of the two laser pulses of FIGS. 4A-4B according to an embodiment.

FIG. 5A illustrates a cross-sectional view of a seal formed with a laser irradiation process having the laser intensity spatial distribution of FIGS. 3A-3B, and FIG. 5B illustrates a cross-sectional view of a seal formed with a laser irradiation process having the laser intensity spatial distributions of FIGS. 4A-4C.

FIG. 6A illustrates the stress level at various regions of the seal of FIG. 5A, and FIG. 6B illustrates the stress level at various regions of the seal of FIG. 5B.

FIG. 7 illustrates a pulse laser irradiation technique in which two different laser pulses are applied, wherein FIG. 7A illustrates the laser intensity spatial distribution of the first pulse being a top hat shape according to an embodiment, and FIG. 7B illustrates the laser intensity spatial distribution of the second pulse being a donut shape according to an embodiment.

FIG. 8 illustrates a pulse laser irradiation technique in which two different laser pulses are applied, wherein FIG. 8A illustrates the laser intensity spatial distribution of the first pulse being a top hat shape according to an embodiment, and FIG. 8B illustrates the laser intensity spatial distribution of the second pulse being a volcano shape according to an embodiment.

FIG. 9 illustrates a pulse laser irradiation technique in which two different laser pulses are applied, wherein FIG. 9A illustrates the laser intensity spatial distribution of the first pulse being a volcano at shape according to an embodiment, and FIG. 9B illustrates the laser intensity spatial distribution of the second pulse being a donut shape according to an embodiment.

FIG. 10 illustrates a pulse laser irradiation technique in which two different laser pulses are applied, wherein FIG. 10A illustrates the laser intensity spatial distribution of the first pulse being a volcano shape according to an embodiment, and FIG. 10B illustrates the laser intensity spatial distribution of the second pulse being a different volcano shape according to an embodiment.

FIG. 11 illustrates a schematic view of the first and second lasers in relation to the venthole, according to an embodiment.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions.

The term “substantially” or “about” may be used herein to describe disclosed or claimed embodiments. The term “substantially” or “about” may modify a value or relative characteristic disclosed or claimed in the present disclosure. In such instances, “substantially” or “about” may signify that the value or relative characteristic it modifies is within ±0%, 0.1%, 0.5%, 1%, 2%, 3%, 4%, 5% or 10% of the value or relative characteristic.

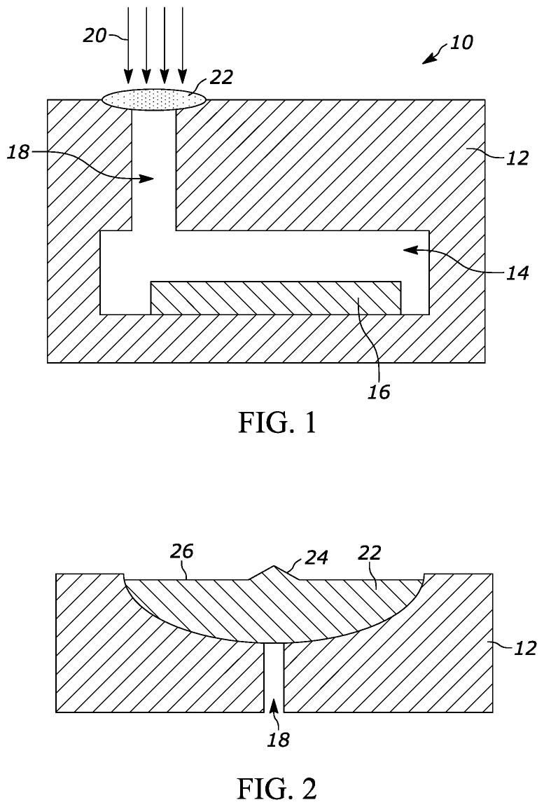

Various micromechanical devices (e.g., microelectromechanical systems (MEMS), inertial measurement units (IMUs) etc.) include a venthole opening leading to a chamber that contains an encapsulated device. In recent years, pulse laser irradiation techniques have been utilized for sealing the venthole opening. These technique seal the venthole opening to encapsulate gasses and critical pressure inside the device chamber of the micromechanical device. For example, FIG. 1 illustrates an example of a micromechanical device 10 sealed according to these techniques. The micromechanical device 10 includes a substrate 12, such as a silicon or other material typically used for integrated circuits in micromechanical devices. The term “substrate” can also refer to one or more films or layers of other material (e.g., polycrystalline silicon, silicon dioxide, etc.) layered above an underlying material (e.g., silicon). The substrate 12 is formed with a chamber 14, also referred to as a cavity or pocket. The chamber 14 houses or encapsulates a device 16, which can be any sort of MEMS device or IMU such as an accelerometer, gyroscope, temperature sensor, pressure sensor, or the like. The substrate 12 is also formed with a venthole 18 which allows for initial air or gas communication between the chamber 14 and the environment outside of the micromechanical device 10, until sealed. The venthole 18 and/or chamber 14 may be formed in the layers or materials above a base substrate, and these layers should be included as part of the term “substrate” unless otherwise stated. Sealing the venthole 18 can prevent gasses or outside environmental factors from affecting the gasses or vacuum inside the chamber 14. To seal the venthole 18, laser irradiation is utilized in which a laser beam 20 is directed at the surface above the venthole 18. This causes some of the material of the substrate 12 above the venthole 18 to melt, creating a seal 22 formed by a melt of the substrate 12.

However, this method oftentimes leaves an issue of surface asperity. For example, FIG. 2 shows a portion of the micromechanical device 10 of FIG. 1 after the laser irradiation process is complete. As can be seen here, the resulting seal 22 (which is a solidified melt of the material of the substrate 12) includes a surface asperity 24, which is a high spot or bump on an upper surface 26 of the seal 22. This surface asperity 24 can be undesirable in some applications because it can make contact with an opposing surface when the micromechanical device 10 is assembled to another component, for example.

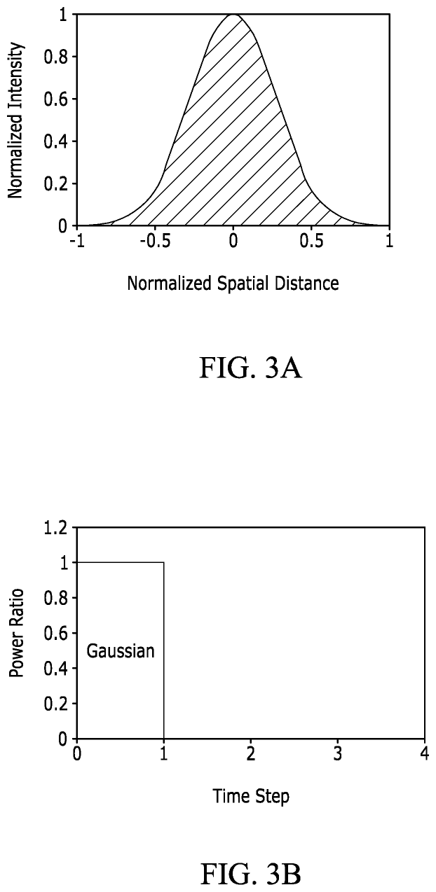

Many laser irradiation processes typically use a laser pulse profile such as the one illustrated in FIGS. 3A-3B. FIG. 3A illustrates a Gaussian (or “bell curve”) distribution of laser intensity, in which the heightened laser intensity is located at or near the center of the venthole with reduced intensity in a direction away from the center of the venthole. This can be referred to as a Gaussian laser intensity spatial distribution. The distribution shown in FIG. 3A is relative to a cross-section of the substrate, such as the views shown in FIGS. 1-2; therefore the laser pulse profile can be referred to as a Gaussian shape or Gaussian cross-section. Also, as shown in FIG. 3B, the laser pulse is given a single, constant power or intensity throughout its laser pulse application, indicated as a flat line from time step 0 to time step 1. Each time step may be a number of nanoseconds, milliseconds, microseconds, or the like depending on the application.

Several solutions have been proposed for improving the laser irradiation process to eliminate or at least improve the presence of surface asperities. For example, U.S. application Ser. No. 17/973,217, filed Oct. 25, 2022, titled LASER SEALING METHODS FOR CLOSING VENTHOLES OF MICROMECAHNICAL DEVICES (which is incorporated by reference herein in its entirety) is directed to methods of sealing ventholes by applying a laser pulse to a trench offset from the substrate. While this is a viable approach for removing or reducing surface asperity for many applications, it is not perfect for all applications.

Therefore, the present disclosure provides various embodiments for further improving the laser irradiation process to further reduce or eliminate the presence of any surface asperities. In some embodiments, the laser pulse profile varies over time for a single venthole sealing procedure. Various laser pulse profiles are disclosed that, when combined, can reduce the surface asperities. Furthermore, the combination of two (or more) different laser pulse profiles reduces the magnitude of stress at or around the venthole, improving structural rigidity and reliability of the seal for the venthole.

The laser pulse profiles, also referred to as a laser intensity spatial distributions, refer to the intensity of the laser pulse in relation to the distance away from the center of the laser pulse, relative to a cross-sectional view of the substrate being subjected to the laser pulse. As will be described below, a first laser pulse can have a first laser intensity spatial distribution, and a subsequent second laser pulse can have a second laser intensity spatial distribution that differs from the first laser intensity spatial distributions. For example, the second laser intensity spatial distribution can take one of a plurality of shapes that has a laser pulse intensity at its center that is less than the center of the first laser intensity spatial distribution.

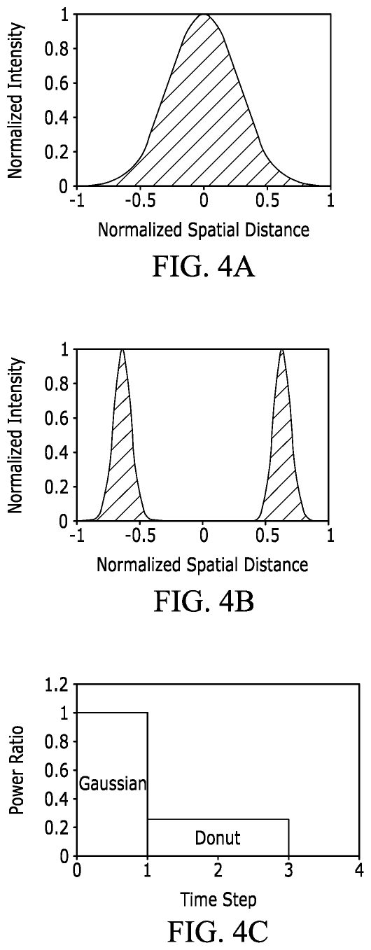

One example of this is illustrated in FIGS. 4A-4C. In this embodiment, once again a Gaussian laser intensity spatial distribution is used for a first time (e.g., from time step 0 to time step 1). Thereafter, a second laser intensity spatial distribution is applied. In this embodiment, a “donut” shaped laser intensity spatial distribution is used, shown in FIG. 4B. Such a donut shape can include a magnitude of laser applied in a ring-shaped region about the center, and little or no laser applied at the center. The result is a donut shape laser intensity spatial distribution when looking top-down at the substrate subjected to the laser irradiation.

The second laser pulse with the second laser intensity spatial distribution (in this case, a donut shape) can be applied to the substrate immediately or instantaneously following the application of the first laser pulse having the first intensity spatial distribution (in this case, a Gaussian shape). This is illustrated in FIG. 4C. Also shown here is an embodiment in which the second laser pulse is applied for a longer time than the first laser pulse. The second laser pulse having the second laser intensity spatial distribution is shown as being applied from time step 1 to time step 3, which is twice as long as the first laser pulse with the first laser intensity spatial distribution. In other embodiments, the length of time that the second laser pulse is applied is more or less than this amount of time illustrated.

While FIG. 4C shows the second laser pulse being applied immediately or instantly following the first laser pulse, in other embodiments there may be a small time gap between the first and second laser pulses. For example, first the Gaussian-shaped pulse can be applied, followed by a short time period in which no laser pulse is applied, and then the donut-shaped pulse can be applied. This sort of time relationship between the first and second pulses can be applicable to any and all embodiments described herein.

The shape of the donut-shaped laser intensity spatial distribution shown in FIG. 4B can vary from what is illustrated. For example, while the laser intensity spatial distribution shown in FIG. 4B shows two distinct Gaussian shapes spaced from the center in which no laser is applied, the two Gaussian shapes can be squared off (i.e., flat on top and flat sides), or the two Gaussian shapes can be more or less steep than shown here.

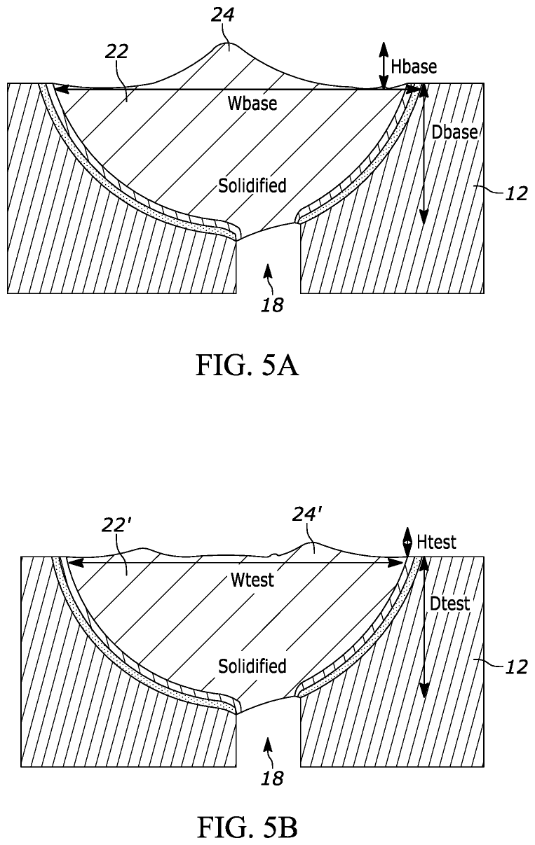

In short, two different laser pulses having two different laser intensity spatial distributions are used to seal the venthole. The result is a seal with reduced surface asperity. FIG. 5A illustrates a cross-sectional view of a seal formed with a laser irradiation process having the laser intensity spatial distribution of FIGS. 3A-3B, and FIG. 5B illustrates a cross-sectional view of a seal formed with a laser irradiation process having the laser intensity spatial distributions of FIGS. 4A-4C. In FIG. 5A, the seal 22 is formed having a width W_{base} and depth D_{base}, and a surface asperity 24 having a height H_{base}. In FIG. 5B, a seal 22′ is formed having a width Wₜₑₛₜ and depth Dₜₑₛₜ, and a surface asperity 24′ having a height Hₜₑₛₜ. While the width Wₜₑₛₜ and depth Dₜₑₛₜ of the seal 22′ are similar (e.g., within 3%) to that of the seal 22, the height Hₜₑₛₜ of the surface asperity 24′ of FIG. 5B is significantly reduced (e.g., by approximately 35%) compared to the height H_{base} of the surface asperity 24 of FIG. 5A. The use of two different laser pulses having two different laser intensity spatial distributions has reduced the size of the surface asperity as compared to when only one laser pulse with a single laser intensity spatial distribution is utilized.

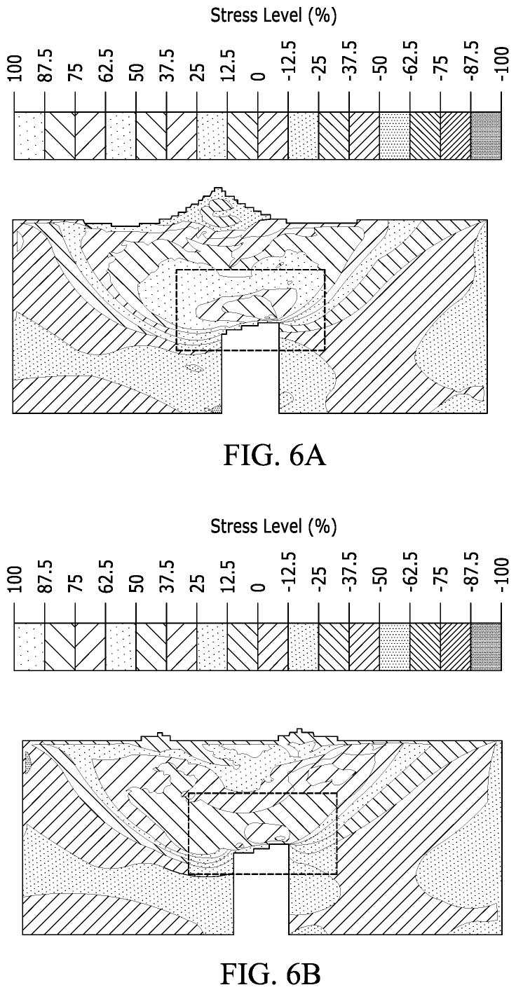

The use of two different laser pulses can also significantly impact the stress level in the micromechanical device. FIG. 6A shows the stress level associated with the seal shown in FIG. 5A, and FIG. 6B shows the stress level associated with the seal shown in FIG. 5B. A dotted box in each Figure represents a high-stress area of the seal. In this region, using two different laser pulses having the laser intensity spatial distributions of FIGS. 4A-4C reduced the stress in the range of 10% to 30%. Although not shown, using other laser intensity spatial distributions disclosed herein also reduced the stress in this region of the seal.

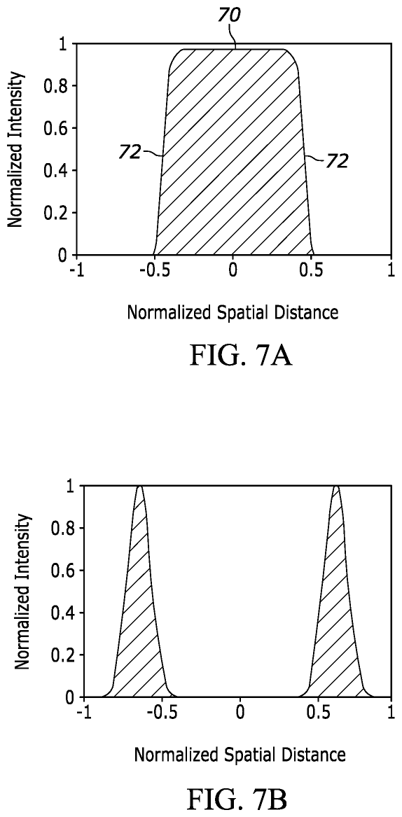

FIGS. 7-10 illustrate additional embodiments of the laser intensity spatial distributions that can be utilized in the laser irradiation process for sealing the venthole. For each Figure, the “A” Figure represents the laser intensity spatial distribution of the first laser, and the “B” Figure represents the laser intensity spatial distribution of the second laser. The second laser is delivered after the first laser, either instantly or after a small delay in which no laser in applied.

FIG. 7 illustrates first and second laser pulses for sealing the venthole in which FIG. 7A illustrates the first laser pulse having a laser intensity spatial distribution of a “top hat” shape, and FIG. 7B illustrates the second laser pulse having a laser intensity spatial distribution of a donut shape. The top hat shape of FIG. 7A may include a plateau 70 of laser pulse intensity at or near a center of the pulse. In this case, the plateau is at or near 1 on the normalized pulse intensity scale (e.g., Y-axis). Additionally, the top hate shape tapers downward from the plateau to zero on either side 72 of the plateau. These tapers or sidewalls 72 are substantially vertical. The steep, substantially vertical sidewalls provide a very small transition between the region of the substrate that is not subjected to the laser pulse and the region of the substrate that is subjected to the laser pulse. 100% laser power can be provided in the center of the laser in the plateau region, with no laser power provided outside of this region. In other words, the laser pulse intensity can be binary, wherein at any spatial distance from the center of the laser, the laser is either at full power or zero power. The donut shape of the second laser pulse can be similar to the donut shape described above in which two Gaussian regions are separated by a space in the center of the laser pulse in which no laser power is provided. In other embodiments, each of these Gaussian regions can be replaced with a uniform (e.g., rectangle, top-hat shape) laser power.

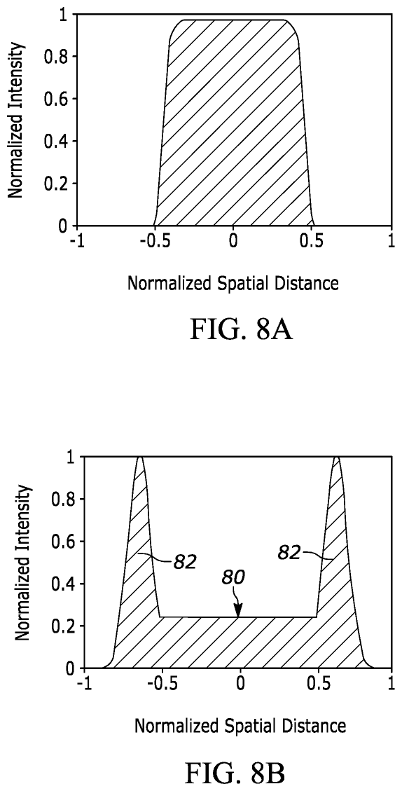

FIG. 8 illustrates first and second laser pulses for sealing the venthole in which FIG. 8A illustrates the first laser pulse having a laser intensity spatial distribution of a “top hat” shape similar to FIG. 7A above, and FIG. 8B illustrates the second laser pulse having a laser intensity spatial distribution of a volcano shape. The volcano shape may be defined by a caldera 80 at or near a center of the second laser pulse, and a pair of sidewalls 82 remote from the center of the second laser pulse. Each of the sidewalls can take a Gaussian shape for example, and can be higher in laser pulse intensity (e.g., 100% laser power) than the center caldera region 82 (e.g., 20% laser power).

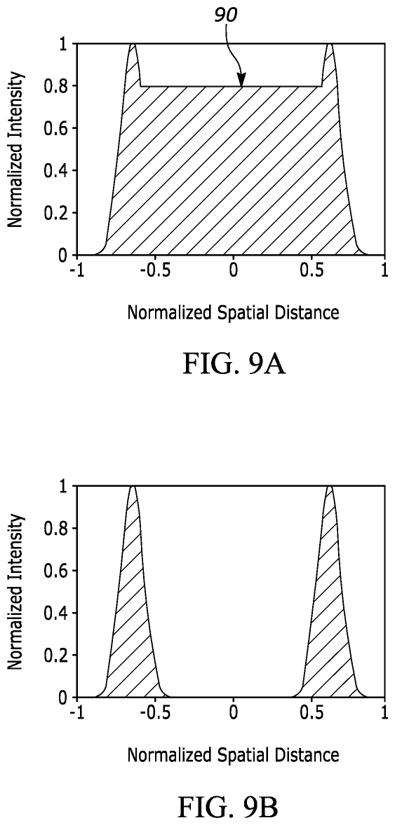

FIG. 9 illustrates first and second laser pulses for sealing the venthole in which FIG. 9A illustrates the first laser pulse having a laser intensity spatial distribution of a volcano shape, and FIG. 9B illustrates the second laser pulse having a laser intensity spatial distribution of a donut shape similar to the donut shapes described above. The volcano shape of FIG. 9A is similar to the volcano shape of FIG. 8B except the laser power or intensity at the center of the laser of FIG. 9A is higher than in FIG. 8B. This creates a volcano-shaped laser intensity spatial distribution having a caldera region 90 with a higher floor than in FIG. 8B.

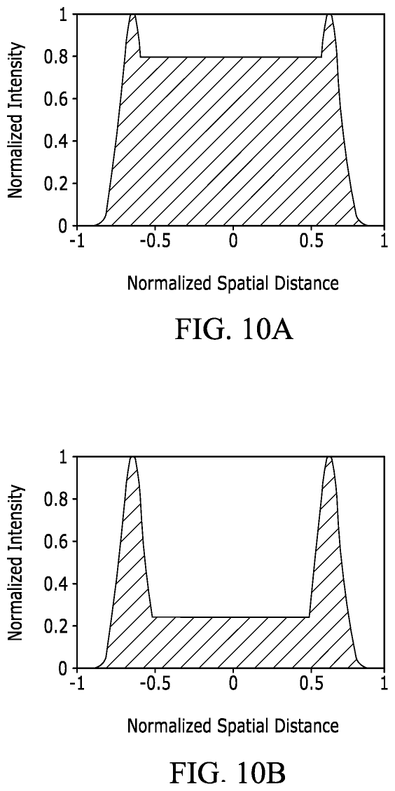

The various shapes of laser intensity spatial distributions described herein can be utilized in either the first laser pulse or the second laser pulse. As an example, FIG. 10 illustrates first and second laser pulses for sealing the venthole in which FIG. 10A illustrates the first laser pulse having a laser intensity spatial distribution of a volcano shape similar to that shown in FIG. 9A, and FIG. 10B illustrates the second laser pulse having a laser intensity spatial distribution of a volcano shape similar to that shown in FIG. 8B. In other embodiments, the donut shape can be used for the first laser pulse, the top hat can be used for the second laser pulse. This disclosure should not be limited to only the combinations of laser pulses shown in the Figures. Moreover, this disclosure should not be limited to only the shapes of laser intensity spatial distributions disclosed herein.

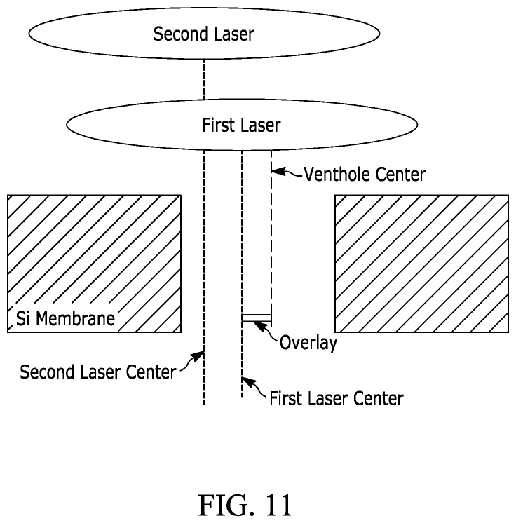

The center of the first laser pulse may not be in the same location of the center of the second laser pulse. For example, FIG. 11 illustrates a first laser pulse having a first laser center, and a second laser pulse having a second laser center. Here, the first laser center does not overlap with the second laser center. For example, the second laser center is located closer to the walls of the venthole than the first laser center. In other embodiments, the first laser center is located closer to the walls of the venthole than the second laser center. Moreover, both of the laser centers may be offset from the center of the venthole. The distance between the venthole center and the first laser center may be different (e.g., more or less) than the distance between the first laser center and the second laser center.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A method of sealing a venthole of a micromechanical device, the method comprising:
applying a first laser pulse to a venthole of a substrate of a micromechanical device for a first time period, wherein the first laser pulse has a first laser intensity spatial distribution, and wherein the venthole leads to a chamber configured to contain a device; and
then applying a second laser pulse to the venthole for a second time period, wherein the second laser pulse has a second laser intensity spatial distribution that is different than the first laser intensity spatial distribution.

2. The method of claim 1, wherein the second time period is different than the first time period.

3. The method of claim 1, wherein the first laser intensity spatial distribution has a Gaussian shape.

4. The method of claim 3, wherein the second laser intensity spatial distribution has a donut shape.

5. The method of claim 4, wherein no laser is applied at a center of the second laser pulse.

6. The method of claim 1, wherein the first laser intensity spatial distribution has a top hat shape.

7. The method of claim 6, wherein the top hat shape includes a plateau of laser pulse intensity at or near a center of the pulse, and a pair of sidewalls leading from the plateau to zero laser intensity, wherein each of the sidewalls is substantially vertical.

8. The method of claim 6, wherein the second laser intensity spatial distribution has a donut shape.

9. The method of claim 6, wherein the second laser intensity spatial distribution has a volcano shape.

10. The method of claim 9, wherein the volcano shape includes a caldera-shaped laser pulse intensity at or near a center of the second laser pulse, and a pair of sidewalls remote from the center with a laser pulse intensity that exceeds that of the caldera.

11. The method of claim 1, wherein the first laser intensity spatial distribution has a volcano shape with a first laser intensity magnitude at a center of the first laser pulse.

12. The method of claim 11, wherein the second laser intensity spatial distribution has a second volcano shape with a second laser intensity magnitude at a center of the second laser pulse, wherein the second laser intensity magnitude differs from the first laser intensity magnitude.

13. The method of claim 1, wherein a center of the first laser pulse is offset from a center of the venthole by a first distance, and a center of the second laser pulse is offset from the center of the venthole by a second distance that exceeds the first distance.

14. A method of sealing a venthole of a micromechanical device, the method comprising:
providing a micromechanical device having a substrate, the substrate having an upper surface, and the substrate defining a venthole leading to a chamber configured to contain a device;
applying a first laser pulse to the substrate at the venthole for a first time period, wherein the first laser pulse has a first laser intensity spatial distribution with a first laser pulse intensity at a center of the first laser pulse; and
applying a second laser pulse to substrate at the venthole for a second time period, wherein the second laser pulse has a second laser intensity spatial distribution that is different than the first laser intensity spatial distribution, and wherein the second laser intensity spatial distribution has a second laser pulse intensity at a center of the second laser pulse that is less than the first laser pulse intensity at the center of the first laser pulse.

15. The method of claim 14, wherein the second time period is different than the first time period.

16. The method of claim 14, wherein the first laser intensity spatial distribution has a Gaussian shape.

17. The method of claim 16, wherein the second laser intensity spatial distribution has a donut shape.

18. The method of claim 14, wherein the center of the first laser pulse is offset from the center of the second laser pulse.

19. A method of controlling surface asperity during laser sealing of a venthole, the method comprising:
applying a first laser pulse to a venthole of a substrate, wherein the first laser pulse has a first laser intensity spatial distribution; and
applying a second laser pulse to the venthole, wherein the second laser pulse has a second laser intensity spatial distribution that differs from the first laser intensity spatial distribution.

20. The method of claim 19, wherein the first laser intensity spatial distribution has a first laser pulse intensity at a center of the first laser pulse, and wherein the second laser intensity spatial distribution has a second laser pulse intensity at a center of the second laser pulse that is less than the first laser pulse intensity.
